(19) United States
(12) Patent Application Publication
(10) Pub. No.: US 2009/0098714 A1
(43) Pub. Date: Apr. 16, 2009

(54) Method for forming III-nitrides semiconductor epilayer on the semiconductor substrate

(75) Inventors: Chun-Yen Chang, Hsinchu (TW); Tsung-Hsi Yang, Hsinchu (TW); Shih-Guo Shen, Hsinchu (TW)

Correspondence Address: BACON & THOMAS, PLLC, 625 SLATERS LANE, FOURTH FLOOR, ALEXANDRIA, VA, 22314-1176, US

(73) Assignee: National Chiao Tung University, Hsinchu (TW)

(21) Appl. No.: 12/010,242

(22) Filed: Jan. 23, 2008

(30) Foreign Application Priority Data
Oct. 15, 2007 (TW) 096138413

(51) Int. Cl. H01L 21/205

(52) U.S. Cl. 438/478; 257/E21.108

(57) ABSTRACT

GaN layer on semiconductor substrate is grown by using GaN nanorod buffer layer. Firstly, semiconductor substrate is cleaned and thermally degassed to remove the contaminant in the growth chamber. After the above step, the GaN nanorods layer is grown under the N-rich condition. Then, GaN epilayer is overgrown on the GaN nanorods layer under the Ga-rich condition for forming Group of III-Nitrides semiconductor layer on the semiconductor substrate.

### BACKGROUND OF THE INVENTION

1. Field of the Invention

The invention relates to a method for forming the III-nitrides semiconductor epilayer on the semiconductor substrate, more particularly to a method for forming III-nitrides semiconductor epilayer on the semiconductor substrate.

2. Description of the Prior Art

As shown in FIG. 1A, as the prior art of the semiconductor manufacturing technology, the Molecular Beam Epitaxy (MBE) specified in the “Characterization of Over grown GaN Layers on Nano-Columns Grown by RF-Molecular Beam Epitaxy, Jpn. J. Appl. Phys. Vol. 40 (2001) pp. L192-L194” is used to form the GaN nanorods 102 on the sapphire substrate 101. It will be used as the buffer layer for the overgrowth of GaN. There is the air gap 105 between the GaN nanorods 102.

Again, as shown in FIG. 1B, the overgrowth is used to grow the GaN epilayer 103 on the GaN nanorods 102 under the Ga-rich condition. The defect 104 shown in FIG. 1B is generated upon the subsequent overgrowth of GaN. It is because the epitaxy lateral overgrowth rate on nanorods is slow. The boundary (defect) of the two-dimensional film is formed between nanorods. New GaN film is formed in the air gap already to become as the bundles, which causes the formation of defect in the GaN epitaxy layer 103 and the stress is not able to be released completely. The relevant position of GaN nanorods 102 and the air gap 105 is shown.

Therefore, the technology will produce the actual defect, except it can not be integrated with the silicon process of semiconductor technology, the characteristics of device is also influenced due to poor thermal conductivity of the sapphire substrate. In addition, there is no sapphire substrate having large area, the large-area overgrowth can not be achieved. Upon the subsequent overgrowth of GaN, the large air gaps are hard to coalescence the film. New GaN will be grown in the air gap. When it is connected to the original nanorod, it will become the nanorod bundle and form the crystal boundary, which can not reduce the defect and release the stress effectively.

Thus, in order to respond the demand of semiconductor technology, the relevant technology of Group of III-nitrides are still to be developed, also to reduce the cost of manpower and time, and to form high-quality Group of III-nitrides semiconductor layer effectively.

### SUMMARY OF THE INVENTION

In accordance with the present invention, a method is provided for forming Group of III-nitrides semiconductor layer on the semiconductor substrate.

The foregoing, as well as additional objects, features and advantages of the invention will be more readily apparent from the following detailed description, which proceeds with reference to the accompanying drawings.

The invention can be integrated with silicon process effectively, because the thermal conductivity of silicon is quite good, and the characteristics of device can be improved. In addition, the size of silicon substrate can be up to 12 inches, which can reduce the cost effectively.

The invention relates to a method for forming Group of III-nitrides semiconductor layer on the semiconductor substrate. First, a semiconductor substrate is provided, and there is a clean surface on the semiconductor substrate. Then, a Group of III-nitrides nanorods buffer layer is formed. Finally, a Group of III-nitrides epilayers is overgrown on the Group of III-nitrides nanorods buffer layer, to form a high-quality Group of III-nitrides semiconductor layer on the semiconductor substrate.

The stress of GaN template on nanorods in the invention can be fully released, because the large strain in the GaN template must release to the unstable of nanorods in the underlayer.

The invention can eliminate the crack problem on the surface of GaN, because the large stress caused by the thermal mismatch between GaN and silicon can reduce by the nanorods buffer layer.

In the invention, the loudspeaker-like shape nanorod is formed on the silicon substrate under the N-rich condition, which is narrow at bottom and wide at top.

In the invention, the GaN overgrowth is under the Ga-rich condition.

Therefore, the foregoing and other advantages and features of the invention will become more apparent from the detailed description of the invention given below with reference to the accompanying drawings.

### BRIEF DESCRIPTION OF THE DRAWINGS

The foregoing aspects and many of the attendant advantages of this invention will become more readily appreciated as well becomes better understood by reference to the following detailed description, when taken in conjunction with the accompanying drawings, wherein:

FIGS. 1A to 1B are diagrams schematically illustrating the prior art;

FIG. 2 is a flow-chart schematically illustrating the embodiment of the invention;

FIG. 3 are illustrations of SEM images of the GaN overgrown by the MBE;

FIG. 4 are illustrations of SEM images of the GaN overgrown by the MOCVD;

FIG. 5 are illustrations of the X-ray diffraction spectrum of GaN overgrown by the MBE; and

FIG. 6 are illustrations of the X-ray diffraction spectrum of GaN overgrown by the MOCVD.

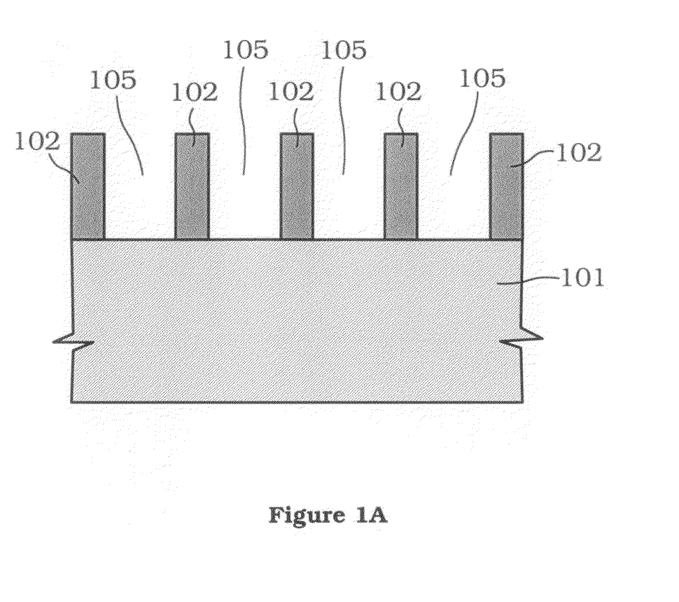

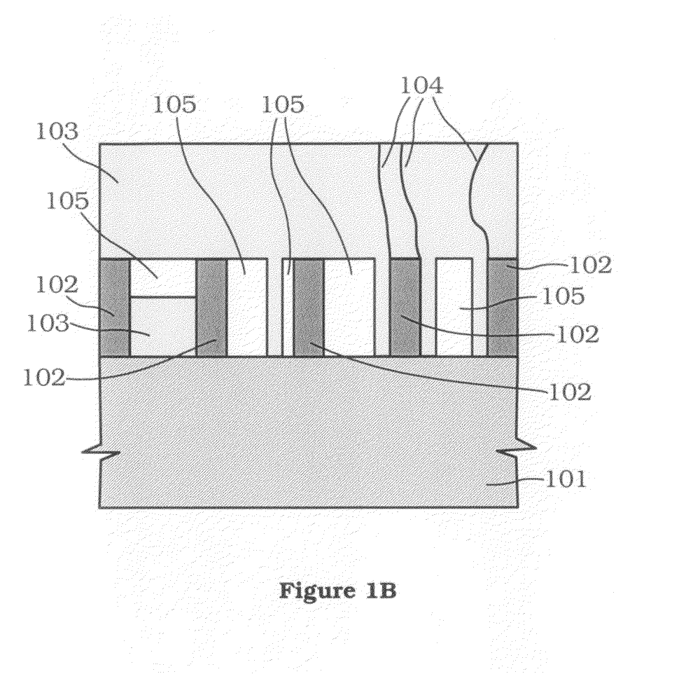

### DESCRIPTION OF THE PREFERRED EMBODIMENT

The following is a description of the present invention. The invention firstly will be described with reference to one exemplary structure. Some variations will then be described as well as advantages of the present invention. A preferred method of fabrication will then be discussed. An alternate, asymmetric embodiment will then be described along with the variations in the process flow to fabricate this embodiment.

The invention uses the loudspeaker-like shape GaN nanorods as the buffer layer. The GaN epilayer is grown on the silicon semiconductor substrate, in order to eliminate high defect intensity, stress and surface crack caused by the formation of GaN (Group of III-nitrides) on the silicon substrate. Normally, the above-mentioned Group of III-nitrides all nitride related synthesis materials.

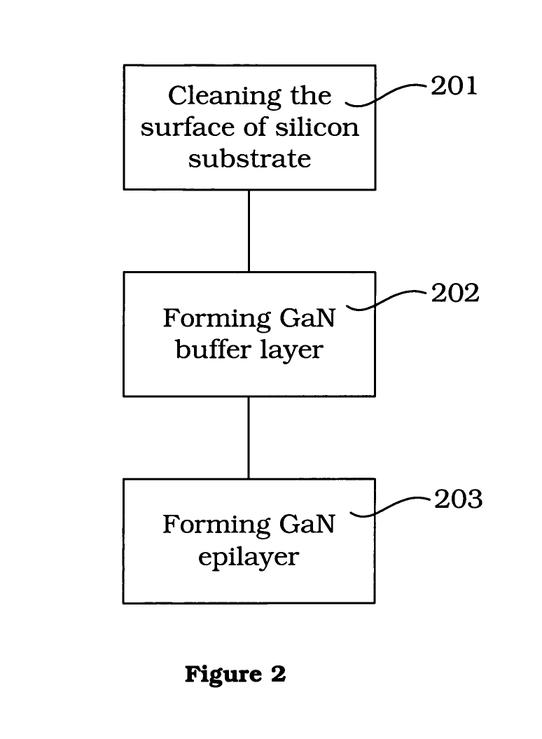

As shown in 201 of FIG. 2, the invention use the silicon semiconductor substrate with (111) orientation as the growth substrate. Firstly, the hydrofluoric acid (HF) is used to remove the oxide on the surface so that the surface is cleaned. However it is not immersed in the deionized water for cleaning. The surface of silicon semiconductor substrate is covered by the fluoride ion, so that the oxide will not be formed in short time period. The fluoride ion, oxide and contaminant are removed by high temperature, in order that the surface reformation of silicon semiconductor substrate can be carried out.

Then, as shown in 202 of FIG. 2, the Molecular Beam Epitaxy (MBE), or Metal-Organic Chemical Vapor Deposition (MOCVD), or Metal Organic Vapor Phase Epitaxy (MOVPE), or Hydride Vapor Phase Epitaxy (HVPE) can used to form the loudspeaker-like shape GaN nanorods buffer layer at about 700□ under the N-rich condition, and it is about 540 nm high. The size is quite uniform and separated clearly between the GaN nanorods and air gap at the half lower part of GaN nanorod. When the height of GaN nanorod is more than 540 nm, the lateral overgrowth will be occurred at the half upper part of GaN nanorod, so that the loudspeaker-like shape is formed.

Then, as shown in 203 of FIG. 2, the MBE or MOCVD is used to form the GaN epilayer on GaN nanorods buffer layer 202 at about 850□ under the Ga-rich condition. The GaN semiconductor layer is formed on the silicon semiconductor substrate. If the MBE is used in the procedure, then the procedure can be completed in the same growth chamber.

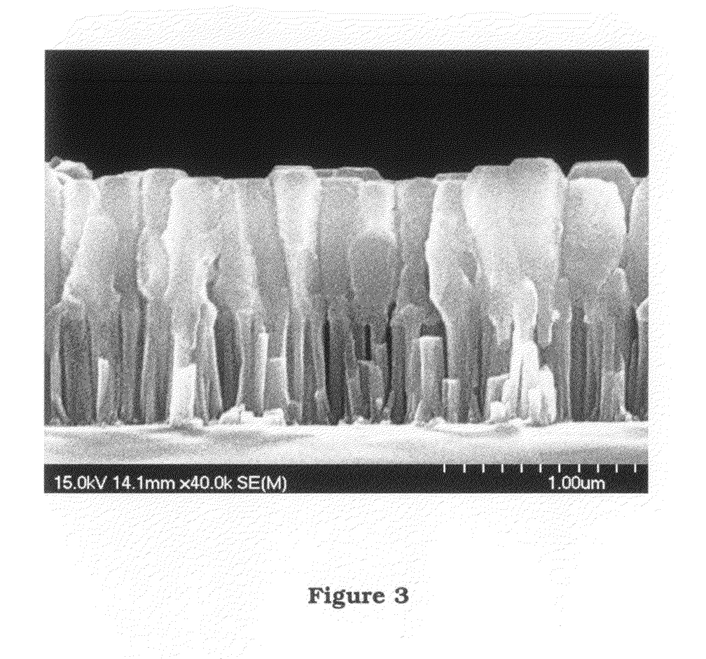

As shown in FIG. 3, the scanning electron microscope (SEM) images of the GaN epilayer overgrown by the MBE are illustrated. From the images, it is known that the GaN epilayer overgrown under Ga-rich condition can form the film quickly.

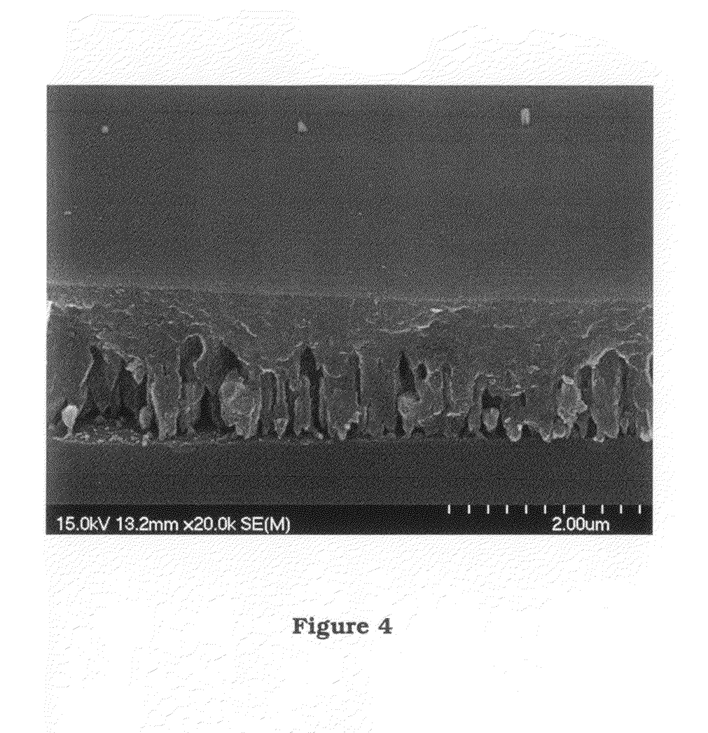

As shown in FIG. 4, the scanning electron microscope (SEM) images of the GaN epilayer overgrown by the MOCVD are shown. From the images, it is known that the GaN epilayer overgrown under Ga-rich condition can form the film completely, and the surface is quite flat.

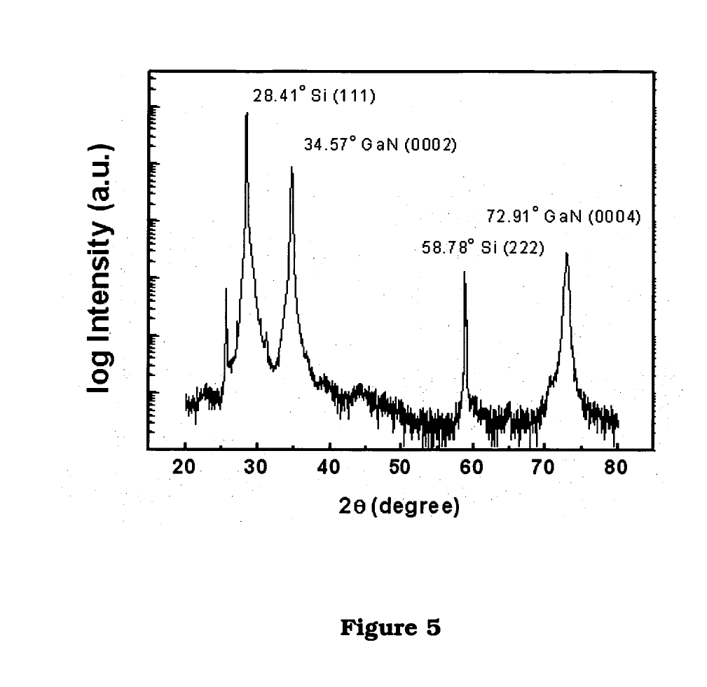

As shown in FIG. 5, the X-ray diffraction spectrum of GaN overgrown by the MBE is shown, wherein 2θ=34.57°. From the Figure, it is shown that the stress has been released completely. The c-axis distance of GaN shall be 5.185 Å. When the c-axis distance is 5.1848 Å for GaN using the GaN nanorods buffer layer, which represents the stress of the GaN epilayer has been fully released, and the quality of single crystal is quite good.

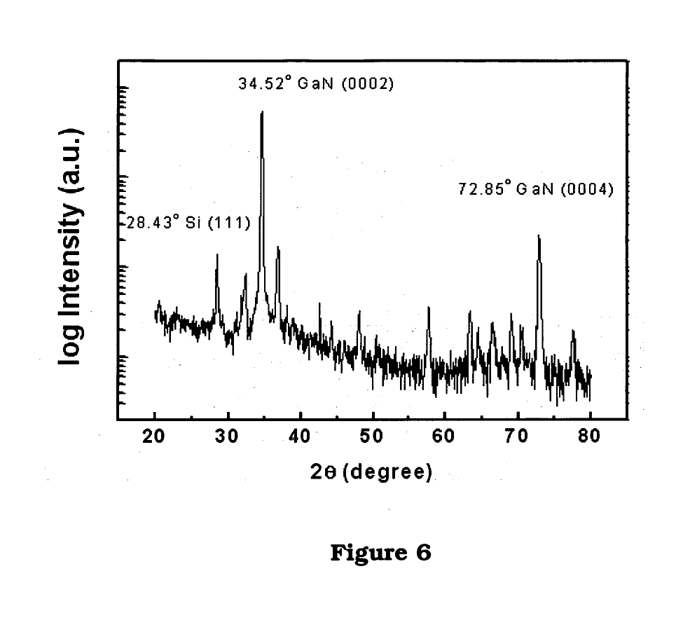

FIG. 6 shows the X-ray diffraction spectrum of GaN overgrown by the MOCVD. From the figure, it is shown that the stress has been released completely. The c-axis distance of GaN shall be 5.1921 Å, which represents the compression stress applying on the GaN epilayer, and the sharp peak at 34.52° of GaN represents the quality of the single crystal is quite good.

Thus, summarizing the above-mentioned description, the invention relates to a method for forming Group of III-nitrides semiconductor layer on the semiconductor substrate. Firstly, a semiconductor substrate is provided, and there is a clean surface on the semiconductor substrate. Then, a Group of III-nitrides nanorods buffer layer is formed. Finally, a Group of III-nitrides epilayer is overgrown on the Group of III-nitrides nanorods buffer layer, to form a high-quality Group of III-nitrides semiconductor layer on the semiconductor substrate.

It is understood that various other modifications will be apparent to and can be readily made by those skilled in the art without departing from the scope and spirit of this invention. Accordingly, it is not intended that the scope of the claims appended hereto be limited to the description as set forth herein, but rather that the claims be construed as encompassing all the features of patentable novelty that reside in the present invention, including all features that would be treated as equivalents thereof by those skilled in the art to which this invention pertains.

What is claimed is:

1. A method for forming Group of III-nitrides semiconductor layer on the semiconductor substrate, comprising:
providing a semiconductor substrate, said semiconductor substrate having a clean surface;
forming a Group of III-nitrides nanorods buffer layer; and
overgrowing a Group of III-nitrides epilayer on the Group of III-nitrides nanorods buffer layer to form a Group of III-nitride s semiconductor layer.

2. The method according to claim 1, wherein the semiconductor substrate comprises silicon semiconductor substrate.

3. The method according to claim 1, wherein the clean surface comprises the hydrofluoric acid cleaning and removing the oxide by high temperature.

4. The method according to claim 1, wherein the method forming the Group of III-nitrides nanorods buffer layer comprises Molecular Beam Epitaxy.

5. The method according to claim 1, wherein the method forming the Group of III-nitrides nanorods buffer layer comprises Metal Organic Vapor Phase Epitaxy.

6. The method according to claim 1, wherein the method forming the Group of III-nitrides nanorods buffer layer comprises Hydride Vapor Phase Epitaxy.

7. The method according to claim 1, wherein the method forming the Group of III-nitrides nanorods buffer layer comprises the Metal-Organic Chemical Vapor Deposition.

8. The method according to claim 1, wherein the method forming the Group of III-nitrides epilayer comprises the Molecular Beam Epitaxy.

9. The method according to claim 1, wherein the method forming the Group of III-nitrides epilayer comprises the Metal-Organic Chemical Vapor Deposition.

10. A method for forming Group of III-nitrides semiconductor on the semiconductor substrate, comprising:
providing a silicon semiconductor substrate, said semiconductor substrate having a clean surface that been cleaned by hydrofluoric acid and by cleaning an oxide under high temperature;
forming a Group of III-nitrides nanorods buffer layer; and
overgrowing a Group of III-nitrides epilayer on the Group of III-nitrides nanorods buffer layer to form a Group of III-nitrides semiconductor layer.

11. The method according to claim 11, wherein the method forming the Group of III-nitrides nanorods buffer layer comprises Molecular Beam Epitaxy.

12. The method according to claim 11, wherein the method forming the Group of III-nitrides nanorods buffer layer comprises Metal Organic Vapor Phase Epitaxy.

13. The method according to claim 11, wherein the method forming the Group of III-nitrides nanorods buffer layer comprises Hydride Vapor Phase Epitaxy.

14. The method according to claim 11, wherein the method forming the Group of III-nitrides nanorods buffer layer comprises the Metal-Organic Chemical Vapor Deposition.

15. The method according to claim 11, wherein the method forming the Group III nitride nanorods buffer layer comprises the Metal-Organic Chemical Vapor Deposition.

16. The method according to claim 11, wherein the method forming the Group III nitride epilayer comprises the Molecular Beam Epitaxy.

17. The method according to claim 11, wherein the method forming the Group III nitride epilayer comprises the Metal-Organic Chemical Vapor Deposition.
